(19) United States
(12) Patent Application Publication
(10) Pub. No.: US 2023/0213876 A1
(43) Pub. Date: Jul. 6, 2023

(54) APPARATUS FOR TREATING SUBSTRATE AND METHOD FOR TREATING A SUBSTRATE

(71) Applicant: SEMES CO., LTD., Cheonan-si (KR)

(72) Inventors: Hyo Won YANG, Seoul (KR); Hyun Yoon, Seoul (KR); Young Ho Park, Incheon (KR); Tae Hee Kim, Yongin-si (KR); In Ki Jung, Hwaseong-si (KR); Kwang Sup Kim, Asan-si (KR)

(73) Assignee: SEMES CO., LTD., Cheonan-si (KR)

(21) Appl. No.: 18/148,127

(22) Filed: Dec. 29, 2022

(30) Foreign Application Priority Data
Dec. 31, 2021 (KR) 10-2021-0193590
May 11, 2022 (KR) 10-2022-0058020

(51) Int. Cl. G03F 7/20; G03F 7/30; G03F 7/40

(52) U.S. Cl. CPC G03F 7/70683; G03F 7/2053; G03F 7/30; G03F 7/40; G03F 7/70025; G03F 7/7085; G03F 7/70825; G03F 1/72

(57) ABSTRACT

The inventive concept provides a substrate treating apparatus. The substrate treating apparatus includes a support unit configured to rotate and support a substrate; a liquid supply unit configured to supply a liquid to the substrate supported on the support unit; and an optical module for heating the substrate supported on the support unit, and wherein the support unit includes a teaching member having a grid displaying a reference point which matches a center of the support unit.

### CROSS-REFERENCE TO RELATED APPLICATIONS

This application claims priority under 35 U.S.C. § 119 to Korean Patent Application No. 10-2021-0193590 filed on Dec. 31, 2021 and Korean Patent Application No. 10-2022-0058020 filed on May 11, 2022, in the Korean Intellectual Property Office, the disclosures of which are incorporated by reference herein in their entireties.

### BACKGROUND

Embodiments of the inventive concept described herein relate to a substrate treating apparatus and a substrate treating method, more specifi cally, a substrate treating apparatus and a substrate treating method for treating a substrate by heating the substrate.

The photolithography process for forming a pattern on the wafer includes an exposing process. The exposing process is an operation which is previously performed for cutting a semiconductor integrated material attached to the wafer into a desired pattern. The exposing process may have various purposes such as forming a pattern for an etching and forming a pattern for the ion implantation. In the exposing process, the pattern is drawn in on the wafer with a light using a mask, which is a kind of ‘frame’. When the light is exposed to the semiconductor integrated material on the wafer, for example, a resist on the wafer, chemical properties of the resist change according to a pattern by the light and the mask. When a developing liquid is supplied to a resist which chemical properties have changed according to the pattern, the pattern is formed on the wafer.

In order to precisely perform the exposing process, the pattern formed on the mask must be precisely manufactured. It must be checked whether the pattern is formed to satisfy a process condition. A large number of patterns are formed on one mask. That is, it takes a lot of time for an operator to inspect all of the large number of patterns to inspect one mask. Accordingly, a monitoring pattern capable of representing one pattern group including a plurality of patterns is formed on the mask. In addition, an anchor pattern that may represent a plurality of pattern groups are formed on the mask. The operator may estimate whether patterns included in one pattern group are good or not through inspecting the monitoring pattern. In addition, the operator may estimate whether the patterns formed on the mask are good or not through inspecting the anchor pattern.

Also, in order to increase an accuracy of the mask inspection, it is preferable that critical dimension of the monitoring pattern and the anchor pattern are the same. A critical dimension correction process is performed additionally to precisely correct a critical dimension of patterns formed at the mask.

FIG. 1 illustrates a normal distribution regarding a first critical dimension CDP1 of the monitoring pattern of the mask and a second critical dimension CDP2 (a critical dimension of the anchor pattern) before a critical dimension correction process is performed during a mask manufacturing process. In addition, the first critical dimension CDP1 and the second critical dimension CDP2 have a size smaller than a target critical dimension. Before the critical dimension correction process is performed, there is a deliberate deviation between the critical dimension of the monitoring pattern and the anchor pattern (CD, critical dimension). And, by additionally etching the anchor pattern in the critical dimension correction process, the critical dimension of these two patterns are made the same. In the process of over-etching the anchor pattern, if the anchor pattern is more over-etched than the monitoring pattern, a difference in the critical dimension of the monitoring pattern and the anchor pattern occurs, and thus the critical dimension of the patterns formed at the mask may not be accurately corrected. When additionally etching the anchor pattern, a precise etching of the anchor pattern should be accompanied.

In the process of performing an etching on the anchor pattern, a treating liquid is supplied to the mask, and the anchor pattern formed on the mask is heated by a laser. In order to precisely target and heat the anchor pattern, a center of the laser irradiation region must be precisely set. An optical module which irradiates the laser with respect to the center of the preset laser irradiation region moves. For example, a distance from the center of the irradiation region of the preset laser to the anchor pattern formed on the mask to be treated is calculated, and based on this, the optical module moves to a respective position and irradiates the laser. If the center of the pre-set laser irradiation region is separated from the center of the mask, and if the optical module can move to a region at which the anchor pattern exists to irradiate the laser, it may move to a different position from an actual anchor pattern position formed on the mask to irradiate the laser. In this case, since the laser cannot be irradiated to the actual anchor pattern, it is difficult to accurately etch the anchor pattern.

### SUMMARY

Embodiments of the inventive concept provide a substrate treating apparatus and a substrate treating method for performing a precise etching a substrate.

Embodiments of the inventive concept provide a substrate treating apparatus and a substrate treating method for precisely heating a specific region of the substrate.

Embodiments of the inventive concept provide a substrate treating apparatus and a substrate treating method for precisely teaching a center of an irradiation region of a laser for precisely irradiating the laser to a specific region of a substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a support unit configured to rotate and support a substrate; a liquid supply unit configured to supply a liquid to the substrate supported on the support unit; and an optical module for heating the substrate supported on the support unit, and wherein the support unit includes a teaching member having a grid displaying a reference point which matches a center of the support unit.

In an embodiment, a top surface of the teaching member is positioned below a bottom surface of the substrate supported on the support unit.

In an embodiment, the optical module includes: a laser unit configured to irradiate a laser to the substrate supported on the support unit through a head nozzle; and an imaging unit configured to acquire an image by imaging a target object through the head nozzle.

In an embodiment, an irradiation direction of the laser irradiated through the head nozzle and an imaging direction imaging the target object through the head nozzle are coaxial.

In an embodiment, the substrate treating apparatus further includes a controller for controlling the support unit and the optical module, and wherein the controller moves the head nozzle to a top side of the teaching member which rotates at a constant speed, acquires an image including the grid by imaging the rotating teaching member, and calculates the number of grids passing through a set region including a center of the image among an entire region of the image during a set time, and moves the center of the head nozzle to the reference point based on a change in the number of grids.

In an embodiment, the controller moves the head nozzle from a position having a large number of grids to a position having a relatively small number of the grids which pass the set region during the set time.

In an embodiment, the controller stops a movement of the head nozzle if the number of grids passing the set region during the set time becomes 0.

In an embodiment, the support unit further comprises a support pin for supporting the substrate, and the teaching member is positioned at a center region which includes a center of the support unit, and the support pin is positioned at an edge region which supports a center region of the support unit.

In an embodiment, the teaching member is detachable from a top part of the support unit.

In an embodiment, the teaching member couples to the top part of the support unit.

In an embodiment, a center of the head nozzle, a center of the laser irradiated through the head nozzle, and a center of the imaging region of the imaging unit match each other.

The inventive concept provides a substrate treating method. The substrate treating method includes a treating a substrate at a treating space; and adjusting a center of a laser irradiated through a head nozzle of an optical module before or after the treating the substrate, and wherein a center of an imaging region which images a target object through the head nozzle of the optical module corresponds to the center of the laser when seen from above, and wherein the head nozzle is moved at the adjusting the center of the laser so the center of the imaging region corresponds to a center of the support unit which supports the substrate at the treating space when seen from above.

In an embodiment, a grid displaying a reference point corresponding to the center of the support unit is positioned at a top part of the support unit.

In an embodiment, the adjusting the center of the laser is performed in a state at which the substrate is taken out from the treating space, and the head nozzle is moved so the center of the imaging region and the reference point correspond.

In an embodiment, the adjusting the center of the laser moves the head nozzle to a top side of the teaching member which rotates at a constant speed, acquires an image including the grid by imaging the rotating teaching member, and calculates the number of grids passing through a set region including a center of the image among an entire region of the image during a set time, and moves the center of the head nozzle to the reference point based on a change in the number of grids.

In an embodiment, the adjusting the center of the laser moves the head nozzle from a position having a large number of grids to a position having a relatively small number of the grids which pass the set region during the set time, and stops a movement of the head nozzle if the number of grids passing the set region during the set time becomes 0.

In an embodiment, the treating the substrate includes supplying a liquid to a substrate supported by the support unit and heating the substrate supported on the support unit with the laser, and the adjusting the center of the laser is performed before the supplying the liquid or after the heating the substrate.

In an embodiment, the substrate includes a mask having a plurality of cells, and the mask includes a first pattern formed within the plurality of cells, and a second pattern formed outside a region at which the cells are formed and which is different from the first pattern, and wherein the heating the substrate irradiates the laser to the second pattern among the first pattern and the second pattern.

The inventive concept provides a substrate treating apparatus for treating a mask having a plurality of cells. The substrate treating apparatus includes a support unit configured to support the mask having a first pattern formed within the plurality of cells, and a second pattern formed outside a region at which the cells are formed and which is different from the first pattern; a liquid supply unit configured to supply a liquid to a mask supported on the support unit; and an optical module for heating the mask supported on the support unit, and wherein the support unit includes: a support pin for supporting the mask; and a teaching member having a grid displaying a reference point which matches the support unit, and wherein the optical module includes: a head nozzle; a laser unit configured to irradiate a laser to the mask through the head nozzle; and an imaging unit configured to image a target object through the head nozzle, and wherein the teaching member is positioned at a center region including a center of the support unit, and the support pin is positioned at an edge region surrounding a center region of the support unit, and a top surface of the teaching member is positioned below a bottom surface of the mask supported on the support unit, and wherein an irradiation direction of the laser irradiated through the head nozzle and an imaging direction imaging the target object through the head nozzle are coaxial, and a center of the laser irradiated through the head nozzle and a center of the imaging region imaging the target object through the head nozzle correspond when seen from above.

In an embodiment, the substrate treating method further includes a controller for controlling the support unit and the optical module, and wherein the controller moves the head nozzle to a top side of the teaching member which rotates at a constant speed, acquires an image including the grid by imaging the rotating teaching member, and calculates the number of grids passing through a set region including a center of the image among an entire region of the image during a set time, and stops a movement of the head nozzle until the number of grids passing the set region during the set time becomes 0.

According to an embodiment of the inventive concept, a substrate may be precisely etched.

According to an embodiment of the inventive concept, a specific region of a substrate may be precisely heated.

According to an embodiment of the inventive concept, a center of an irradiation region of a laser for precisely irradiating the laser to a specific region of a substrate may be precisely taught.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a normal distribution of a critical dimension of a monitoring pattern and a critical dimension of an anchor pattern.

FIG. 2 is a plan view schematically illustrating a substrate treating apparatus according to an embodiment of the inventive concept.

FIG. 3 schematically illustrates a substrate treated in a chamber of FIG. 2 seen from above.

FIG. 4 is an enlarged view schematically illustrating an embodiment of a second pattern formed on the substrate of FIG. 3 seen from above.

FIG. 5 schematically illustrates an embodiment of the chamber when seen from above, in a state at which the substrate is supported on the support unit of FIG. 4.

FIG. 6 schematically illustrates an embodiment of the chamber when seen from above, in a state at which the substrate is not supported on the support unit of FIG. 4.

FIG. 7 schematically illustrates the optical module according to an embodiment of FIG. 4 viewed from a side.

FIG. 8 schematically illustrates the optical module according to an embodiment of FIG. 4 seen from above.

FIG. 9 schematically illustrates a support unit and a teaching member according to another embodiment of FIG. 4 when seen from the front.

FIG. 10 is a perspective view of the teaching member.

FIG. 11 is a flowchart of a substrate treating method according to an embodiment of the inventive concept.

FIG. 12 is a block diagram schematically illustrating an order of a teaching step of FIG. 11.

FIG. 13 illustrates a state in which the head nozzle is upwardly moved from a top side of the grid in the teaching step of FIG. 11.

FIG. 14 illustrates an image in a set region among images of a grid acquired through a head nozzle which has moved upwardly in the grid of FIG. 13 in a time order.

FIG. 15 illustrates a state in which a center of an imaging region moves to a reference point of the grid in the teaching step of FIG. 11.

FIG. 16 schematically illustrates an image in a set region among images of the grid acquired through the head nozzle of FIG. 15.

FIG. 17 is a flowchart of the substrate treating method according to another embodiment of the inventive concept of FIG. 11.

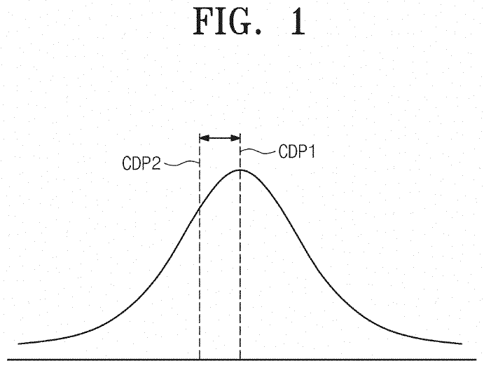

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

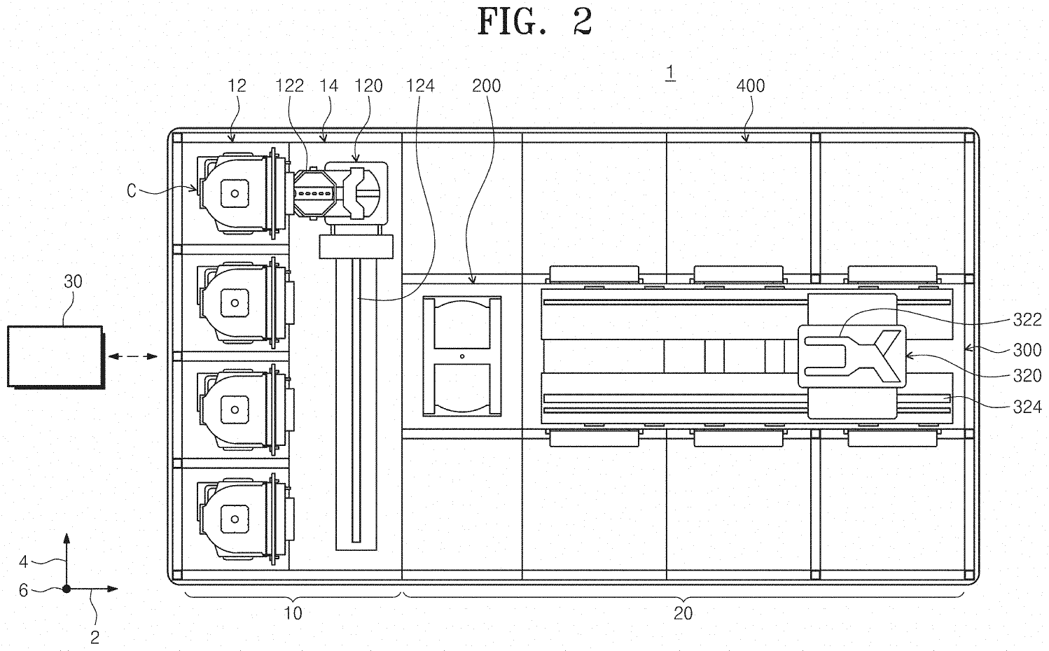

Hereinafter, an embodiment of the inventive concept will be described in detail with reference to FIG. 2 to FIG. 17. FIG. 2 is a plan view schematically illustrating a substrate treating apparatus according to an embodiment of the inventive concept.

Referring to FIG. 2, the substrate treating apparatus 1 includes an index module 10, a treating module 20, and a controller 30. According to an embodiment, when seen from above, the index module 10 and the treating module 20 may be disposed along a direction.

Hereinafter, a direction in which the index module 10 and the treating module 20 are disposed is defined as a first direction 2, a direction perpendicular to the first direction 2 when seen from above is defined as a second direction 4, and a direction perpendicular to a plane including both the first direction 2 and the second direction 4 is defined as a second direction 6.

The index module 10 transfers a substrate M. The index module 10 transfers the substrate M between a container F in which the substrate M is stored and the treating module 20. For example, the index module 10 transfers the substrate M on which a predetermined treatment has been completed at the treating module 20 to the container F. For example, the index module 10 transfers the substrate on which a predetermined treatment has been completed at the treating module 20 from the container F to the treating module 20. A lengthwise direction of the index module 10 may be formed in the second direction 4.

The index module 10 may have a load port 12 and an index frame 14. The container F in which the substrate M is stored is seated on the load port 12. The load port 12 may be positioned on an opposite side of the treating module 20 with respect to the index frame 14. A plurality of load ports 12 may be provided in the index module 10. The plurality of load ports 12 may be arranged in a line along the second direction 4. The number of load ports 12 may increase or decrease according to a process efficiency and foot print conditions, etc. of the treating module 20.

As the container F, a sealing container such as a front opening unified pod (FOUP) may be used. The container F may be placed on the load port 12 by a transfer means (not shown) such as an overhead transfer, an overhead conveyor, or an automatic guided vehicle, or by an operator.

The index frame 14 may have a transfer space for transferring the substrate M. An index robot 120 and an index rail 124 may be provided at the transfer space of the index frame 14. The index robot 120 transfers the substrate M. The index robot 120 may transfer the substrate M between the index module 10 and the buffer unit 200 to be described later. The index robot 120 includes an index hand 122.

The substrate M may be placed on the index hand 122. The index hand 122 may be provided to be forwardly and backwardly movable, rotatable in the vertical direction (for example, the third direction 6), and movable along an axial direction. A plurality of index hands 122 may be provided to be placed at a transfer space of the index frame 14. The plurality of index hands 122 may each be spaced apart from each other in an up/down direction. The plurality of hands 122 may be forwardly and backwardly movable independently of each other.

The index rail 124 is placed in the transfer space of the index frame 14. The index rail 124 may be provided with its lengthwise direction parallel to the second direction 4. The index robot 120 may be placed on the index rail 124, and the index robot 120 may be movable along the index rail 124. That is, the index robot 120 may forwardly and backwardly move along the index rail 124.

The controller 30 may comprise a process controller consisting of a microprocessor (computer) that executes a control of the substrate treating apparatus 1, a user interface such as a keyboard via which an operator inputs commands to manage the substrate treating apparatus 1, and a display showing the operation situation of the substrate treating apparatus 1, and a memory unit storing a treating recipe, i.e., a control program to execute treating processes of the substrate treating apparatus 1 by controlling the process controller or a program to execute components of the substrate treating apparatus 1 according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The controller 30 can control components of the substrate treating apparatus 1 so the substrate treating method described below can be performed. For example, the controller 30 may control components included in the chamber 400 mentioned below.

The treating module 20 may include a buffer unit 200, a transfer frame 300, and a chamber 400.

The buffer unit 200 has a buffer space. The buffer space functions as a space in which the substrate M taken into the treating module 20 and the substrate M taken out from the treating module 20 temporarily remain. The buffer unit 200 may be disposed between the index frame 14 and the transfer frame 300. The buffer unit 200 may be positioned at an end of the transfer frame 300. The slots (not shown) on which the substrate M is placed may be installed in the buffer unit 200. A plurality of slots (not shown) may be installed within the buffer unit 200. The plurality of slots (not shown) may be vertically spaced apart from each other.

In the buffer unit 200, a front face and a rear face are opened. The front face may be a surface facing the index frame 14. The rear face may be a surface facing the transfer frame 300. The index robot 120 may access the buffer unit 200 through the front face. The transfer robot 320 to be described later may access the buffer unit 200 through the rear face.

The transfer frame 300 provides a space for transferring the substrate M between the buffer unit 200 and the chamber 400. The transfer frame 300 may have a lengthwise direction in a direction horizontal to the first direction 2. The chambers 400 may be disposed on the side of the transfer frame 300. The transfer frame 300 and the chamber 400 may be disposed in the second direction 4. According to an embodiment, the chambers 400 may be disposed on both side surfaces of the transfer frame 300. The chambers 400 disposed on a side of the transfer frame 300 may have an array of A×B (A, B are natural numbers greater than 1 or 1), respectively, along the first direction 2 and the second direction 6.

The transfer frame 300 has a transfer robot 320 and a transfer rail 324. The transfer robot 320 transfers the substrate M. The transfer robot 320 transfers the substrate M between the buffer unit 200 and the chamber 400. The transfer robot 320 includes a hand 322 on which the substrate M is placed. The substrate M may be placed on the hand 322. The hand 322 may be forwardly and backwardly movable, rotatable in a vertical direction (e.g., the third direction 6) as an axis, and movable in an axial direction (e.g., the third direction 6). The transfer robot 320 may include a plurality of hands 322. The plurality of hands 322 may be disposed to be spaced apart in the vertical direction. In addition, the plurality of hands 322 may be forwardly and backwardly movable independently of each other.

The transfer rail 324 may be formed in the transfer frame 300 in a direction horizontal to a lengthwise direction of the transfer frame 300. For example, the lengthwise direction of the transfer rail 324 may be a direction horizontal to the first direction 2. The transfer robot 320 is placed on the transfer rail 324, and the transfer robot 320 may move forwardly and backwardly along the transfer rail 324.

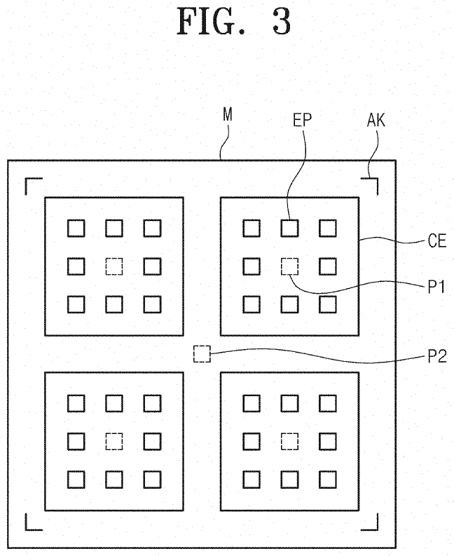

FIG. 3 schematically illustrates the substrate treated in the chamber of FIG. 2 seen from above. Hereinafter, the substrate M treated in the chamber 400 according to an embodiment of the inventive concept will be described in detail referring to FIG. 3.

An object to be treated in the chamber 400 illustrated in FIG. 3 may be any one of a wafer, a glass, and a photo mask. The substrate M treated in the chamber 400 according to an embodiment of the inventive concept may be a photomask which is a “frame” used during an exposing process. For example, the substrate M according to an embodiment may have a rectangular shape. A reference mark AK, a first pattern P1, and a second pattern P2 may be formed on the substrate M.

At least one reference mark AK may be formed on the substrate M. For example, the reference mark AK is a number corresponding to the number of corners of the substrate M and may be formed in a corner region of the substrate M.

The reference mark AK may be used to align the substrate M. In addition, the reference mark AK may be a mark used to determine whether a distortion has occurred during a process of supporting the support unit 420 to be described later. Also, the reference mark AK may be used to derive a position information of the substrate M supported by the support unit 420. For example, the imaging unit 700 to be described later may acquire an image including the reference mark AK by imaging the reference mark AK, and transmit the acquired image to the controller 30. The controller 30 may detect an accurate position of the substrate M, whether the substrate is distorted, etc. by analyzing the image including the reference mark AK. In addition, the reference mark AK may be used to derive the position information of the substrate M when the transfer robot 320 transfers the substrate M. Accordingly, the reference mark AK may be defined as a so-called align key.

A cell CE may be formed on the substrate M. At least one cell may be formed at the substrate M. A plurality of patterns may be formed in each of the plurality of cells CE. The patterns formed in each cell CE may include an exposure pattern EP and a first pattern P1. The patterns (for example, the first patten P1 and the exposure pattern EP) formed at each cell CE may be defined as one pattern group.

The exposure pattern EP may be used to form an actual pattern on the substrate M. The first pattern P1 may be a pattern representing the exposure patterns EP formed in one cell CE. If a plurality of cells CE are formed on the substrate M, a plurality of first patterns P1 may be provided at the cell CE. For example, a first pattern P1 may be formed in each of a plurality of cells CE. However, the inventive concept is not limited thereto, and the plurality of first patterns P1 may be formed in one cell CE.

The first pattern P1 may have a shape in which some of the exposure patterns EP are combined. The first pattern P1 may be defined as a so-called monitoring pattern. An average value of a critical dimension of the plurality of first patterns P1 may be defined as a critical dimension monitoring macro (CDMM).

If the operator inspects the first pattern P1 formed in any one cell CE through a scanning electron microscope (SEM), it is possible to estimate whether the shapes of the exposure patterns EP formed in any one cell CE are good or not. Accordingly, the first pattern P1 may function as an inspection pattern. Unlike the above-described example, the first pattern P1 may be any one of the exposure patterns EPs participating in an actual exposing process. Selectively, the first pattern P1 may be the inspection pattern and may be a pattern participating in an actual exposing process at the same time.

The second pattern P2 may be formed outside the cells CE formed on the substrate M. For example, the second pattern P2 may be formed in an outer region of a region at which a plurality of cells CE are formed. The second pattern P2 may be a pattern representing the exposure patterns EP formed on the substrate M. The second pattern P2 may be defined as an anchor pattern. At least one or more second patterns P2 may be formed. A plurality of second patterns P2 may be formed on the substrate M. The plurality of second patterns P2 may be arranged in a combination of series and/or parallel. For example, five second patterns P2 may be formed on the substrate M, and five second patterns P2 may be arranged in a combination of two rows and three rows. Selectively, the plurality of second patterns P2 may have a shape in which some of the first patterns P1 are combined.

If the operator inspects the second pattern P2 through a scanning electron microscope (SEM), it is possible to estimate whether the shapes of the exposure patterns EPs formed on one substrate M are good or not. Accordingly, the second pattern P2 may function as an inspection pattern. The second pattern P2 may be an inspection pattern which does not participate in an actual exposing process. In addition, the second pattern P2 may be a pattern for setting a process condition of the exposure apparatus.

Hereinafter, the chamber 400 according to an embodiment of the inventive concept is explained. Also, a treating process performed in the chamber 400 to be described later may be a Fine Critical Dimension Correction (FCC) in a mask manufacturing process for the exposing process.

In addition, the substrate M treated in the chamber 400 may be the substrate M on which a pre-treatment has been performed. The critical dimensions of the first pattern P1 and the second pattern P2 formed on the substrate M taken into the chamber 400 may be different from each other. According to an embodiment, a critical dimension of the first pattern P1 may be relatively greater than a critical dimension of the second pattern P2. For example, the critical dimension of the first pattern P1 may have a first width (e.g., 69 nm), and the critical dimension of the second pattern P2 may have a second width (e.g., 68.5 nm).

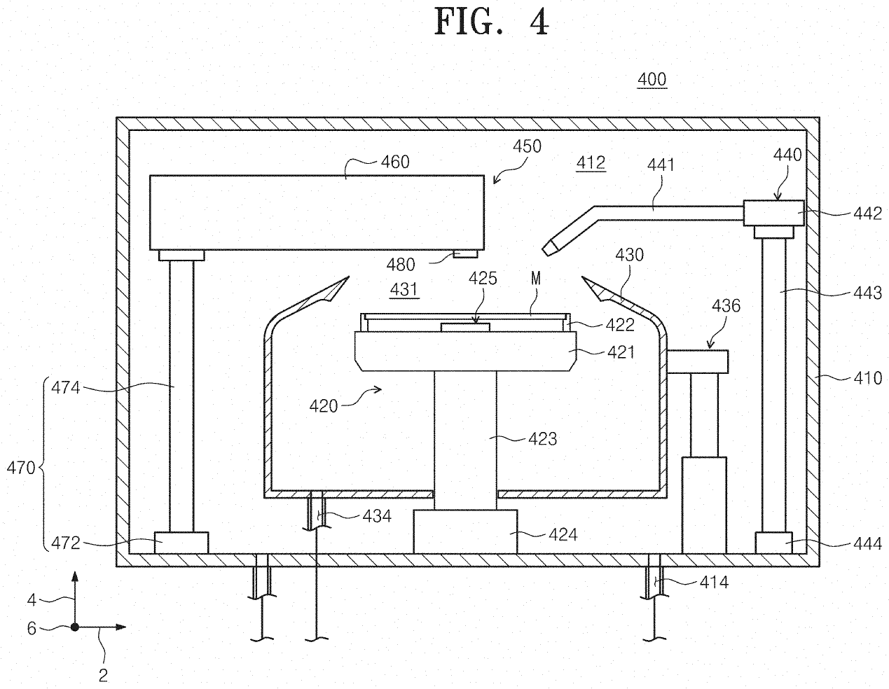

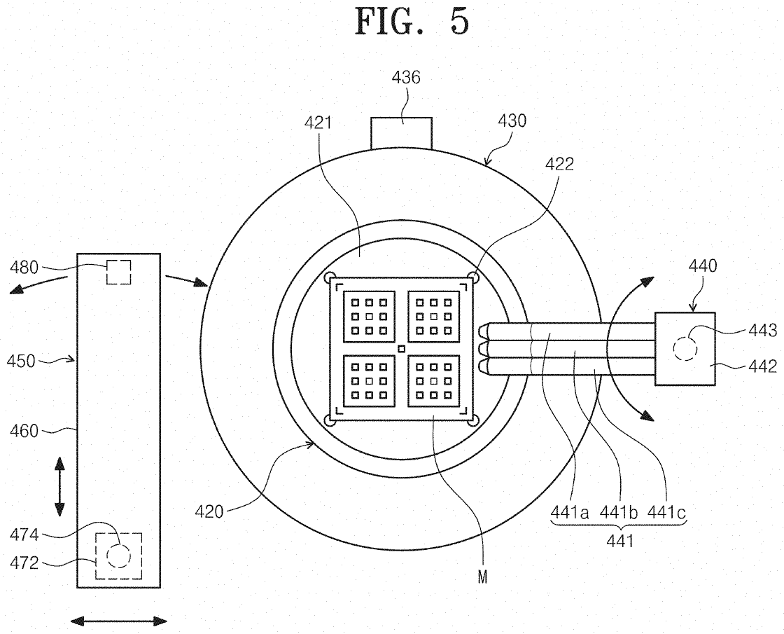

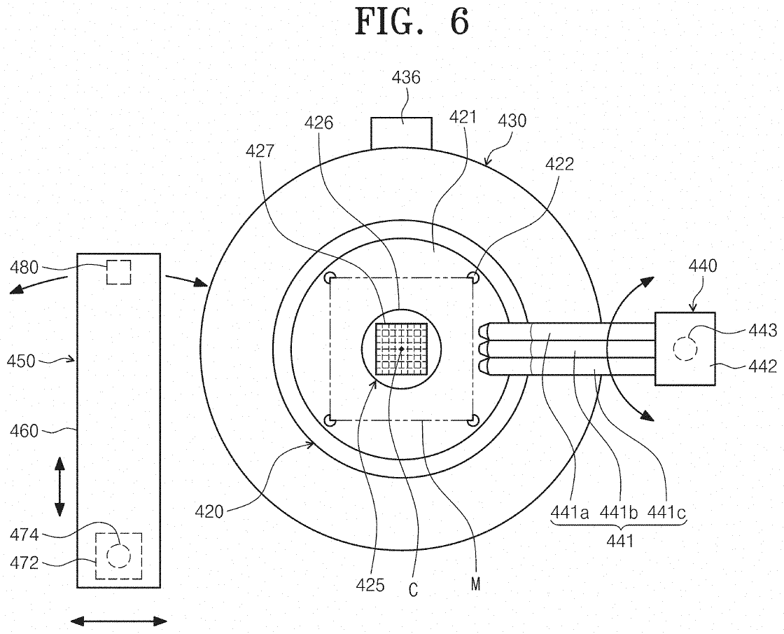

FIG. 4 schematically illustrates an embodiment of the chamber of FIG. 2. FIG. 5 schematically illustrates a state in which the chamber is seen from above while the substrate is supported by the support unit of FIG. 4. FIG. 6 schematically illustrates a state in which the chamber is seen from above while the substrate is not supported by the support unit of FIG. 4.

Referring to FIG. 4 to FIG. 6, the chamber 400 may include a housing 410, a support unit 420, a treating container 430, a liquid supply unit 440, and an optical module 450.

The housing 410 may have a substantially rectangular shape. The housing 410 has an inner space 412. The support unit 420, the treating container 430, the liquid supply unit 440, and the optical module 450 may be positioned in the inner space 412.

An opening (not shown) through which the substrate M is taken out may be formed at the housing 410. The opening (not shown) may be selectively opened and closed by a door assembly which is not shown. An inner wall surface of the housing 410 may be coated with a material having a high corrosion resistance with respect to a liquid supplied by the liquid supply unit 440 to be described later.

An exhaust hole 414 is formed on a bottom surface of the housing 410. The exhaust hole 414 is connected to a depressurizing member (not shown). For example, the depressurizing member (not shown) may be a pump. The exhaust hole 414 exhausts an atmosphere of the inner space 412. In addition, the exhaust hole 414 discharges byproducts such as particles generated in the inner space 412 to the outside of the inner space 412.

The support unit 420 is positioned in the inner space 412. The support unit 420 supports the substrate M. In addition, the support unit 420 rotates the substrate M. The support unit 420 may include a body 421, a support pin 422, a support shaft 423, a driver 427, and a teaching member 425.

The main body 421 may generally have a plate shape. The main body 421 may have a plate shape having a predetermined thickness. A top surface of the main body 421 may have a substantially circular shape when seen from above. The top surface of the main body 421 may have a relatively larger area than the top and bottom surfaces of the substrate M.

The support pin 422 supports the substrate M. The support pin 422 may support the substrate M to separate the bottom surface of the substrate M from the top surface of the main body 421. The support unit 422 may be positioned at an edge region of the main body 421 when seen from above. The edge region of the main body 421 may be defined as a region which surrounds a center region including a center of the main body 421. The support unit 420 may include a plurality of support pins 422. For example, there may be four supporting pins 422. The plurality of support pins 422 may each be disposed at each of the corner regions of the substrate M having a rectangular shape.

The support pin 422 may have a substantially circular shape when seen from above. The support pin 422 may have a shape in which a portion corresponding to a corner region of the substrate M is downwardly recessed. The support pin 422 may have a first surface and a second surface. For example, the first surface may support a bottom end of the corner region of the substrate M. In addition, the second surface may face a side end of the corner region of the substrate M. Accordingly, the second surface may limit a lateral separation of the substrate M if the substrate M rotates.

The support shaft 423 has its lengthwise direction in the vertical direction. The support shaft 423 is coupled to the main body 421. The support shaft 423 is coupled to a bottom part of the main body 421. The support shaft 423 may move in the vertical direction (e.g., in the second direction 6) by the driver 424. In addition, the support shaft 423 may be rotated by the driver 424. The driver 424 may be a motor. If the driver 424 rotates the support shaft 423, the main body 421 coupled to the support shaft 423 may rotate. Accordingly, the substrate M may rotate together with a rotation of the main body 421 through the support pin 422.

The teaching member 425 may teach a center position of the irradiation region of the laser irradiated through the head nozzle 480 to be described later. In addition, the teaching member 425 may teach a center position of the imaging region for imaging a target object through the head nozzle 480.

As shown in FIG. 6, the teaching member 425 may include a body 426 and a grid 427. The body 426 may be coupled to the main body 421. The body 426 may be coupled to a top part of the main body 421. When viewed from above, the body 426 may be disposed in a center region including the center of the main body 421. According to an embodiment, the body 426 and the main body 421 may be integrally formed. A grid 427 may be provided on a top surface of the body 426. According to an embodiment, the body 426 may have a substantially cylindrical shape. However, the inventive concept is not limited thereto, and the body 426 may be deformed into various shapes.

The grid 427 may be positioned on the top surface of the body 426. The grid 427 may be a plate having a grid pattern engraved thereon. A reference point C may be displayed at a center of the grid 427. The reference point C may be positioned to overlap the center of the main body 421 when viewed from above. In addition, in a state in which the substrate M is seated on the support pin 422, the reference point C may overlap the center of the substrate M.

That is, the center of the reference point C, the center of the main body 421 and the center of the substrate M supported by the support unit 420 may overlap each other when viewed from above. The grid 427 and the body 426 may be integrally formed. For example, the top end of the grid 427 and the top end of the body 426 may have a same height.

As shown in FIG. 4, in a state in which the substrate M is seated on the support pin 422, the substrate M and the grid 427 may be spaced apart from each other. According to an embodiment, in a state in which the substrate M is seated on the support pin 422, a bottom surface of the substrate M may be positioned above the a top surface of the grid 427. That is, if the substrate M is seated on the support pin 422, the grid 427 and the body 426 may be disposed at a position which does not interfere with the substrate M.

The treating container 430 may have a cylindrical shape with an open top. The inner space of the treating container 430 with the open top functions as a treating space 431. For example, the treating space 431 may be a space in which the substrate M is liquid-treated and/or heat-treated. The treating container 430 can prevent a liquid supplied to the substrate M from scattering to the housing 410, the liquid supply unit 440, and the optical module 450.

An opening into which the support shaft 423 is inserted may be formed on the bottom surface of the treating container 430. The opening and the support shaft 423 may overlap when seen from above. Also, a discharge hole 434 through which the liquid supplied by the liquid supply unit 440 may be discharged to the outside may be formed on the bottom surface of the treating container 430. The liquid discharged through the discharge hole 434 may be transferred to an outer regeneration system which is not shown. A side surface of the treating container 430 may upwardly extend from the bottom surface of the treating container 430. The top end of the treating container 430 may be inclined. For example, the top end of the treating container 430 may upwardly extend with respect to the ground toward the substrate M supported by the support unit 420.

The treating container 430 may be coupled to a lifting/lowering member 436. The lifting/lowering member 436 may move the treating container 430 in the vertical direction (e.g., in the third direction 6). The lifting/lowering member 436 may move the treating container 430 upward while the substrate M is liquid-treated or heated. In this case, a top end of the treating container 430 may be positioned relatively higher than the top end of the substrate M supported by the support unit 420. In a case in which the substrate is taken into the inner space 412, and a case in which the substrate M is taken out of the inner space 412, the lifting/lowering member 436 may downwardly move the treating container 430. In this case, the top end of the treating container 430 may be positioned relatively lower than the top end of the support unit 420.

The liquid supply unit 440 supplies the liquid to the substrate M. The liquid supply unit 440 may supply a treating liquid to the substrate M. For example, the treating liquid may be an etching liquid or a rinsing liquid. The etching liquid may be a chemical. The etching liquid may etch a pattern formed on the substrate M. The etching liquid may be referred to as an etchant. The etchant may be a mixture of an ammonia, a water, and a liquid including a mixed liquid added with additives and a hydrogen peroxide. The rinsing liquid may clean the substrate M. The rinsing liquid may be provided as a known chemical liquid.

The liquid supply unit 440 may include a nozzle 441, a fixing body 442, a rotation shaft 443, and a rotation driver 444.

The nozzle 441 supplies the liquid to the substrate M supported by the support unit 420. An end of the nozzle 441 may be coupled to the fixing body 442, and the other end of the nozzle 441 may extend in a direction away from the fixing body 442. According to an embodiment, the other end of the nozzle 441 may be bent and extended by a predetermined angle in a direction toward the substrate M supported by the support unit 420.

As illustrated in FIG. 5 and FIG. 6, the nozzle 441 may include a first nozzle 441a, a second nozzle 441b, or a third nozzle 441c. The first nozzle 441a, the second nozzle 441b, and the third nozzle 441c may supply different kinds of liquids to the substrate M.

For example, one of the first nozzle 441a, the second nozzle 441b, and the third nozzle 441c may supply the chemical among the above-described treating liquid to the substrate M. In addition, the first nozzle 441a, the second nozzle 441b, and the third nozzle 441c may supply the rinsing liquid among the above-described treating liquid to the substrate M. Another one of the first nozzle 441a, the second nozzle 441b, and the third nozzle 441c may supply a chemical which is a different type or which has a different concentration from the chemical supplied by any one of the first nozzle 441a, the second nozzle 441b, and the third nozzle 441c.

As shown in FIG. 4, the fixing body 442 fixes and supports the nozzle 441. The fixing body 442 is coupled to the rotation shaft 443. An end of the rotation shaft 443 is coupled to the fixed body 442, and the other end of the rotation shaft 443 is coupled to the rotation driver 444. The rotation shaft 443 has its longitudinal direction in a vertical direction (e.g., a third direction 6). The rotation driver 444 rotates the rotation shaft 443. If the rotation driver 444 rotates the rotation shaft 443, the fixed body 442 coupled to the rotation shaft 443 may rotate based on an axis of the vertical direction. Accordingly, a discharge port of the nozzle 441 may move between a liquid supply position and a standby position. The liquid supply position may be a position for the liquid supply unit 420 to supply the liquid to the substrate M supported by the support unit 420. The standby position may be a position at which the liquid is not supplied to the substrate M and stands by. For example, the standby position may be a position including an outer region of the treating container 430. A home port (not shown) at which the nozzles 441 may stand by may be provided at the standby position at which the nozzle 441 stands by.

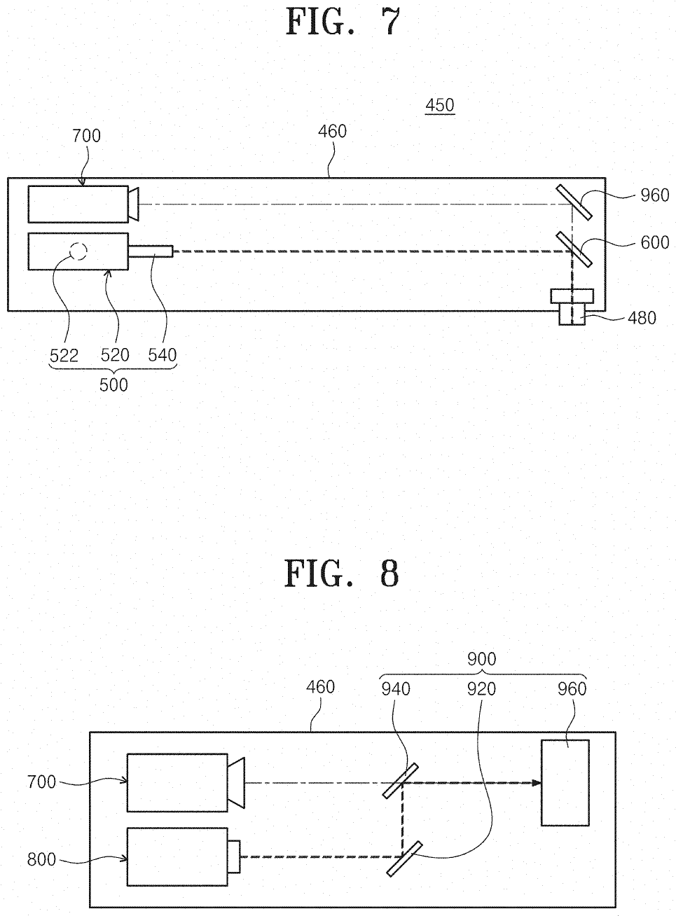

FIG. 7 is a side view schematically illustrating the optical module according to an embodiment of FIG. 4. FIG. 8 is a top view schematically illustrating the optical module according to an embodiment of FIG. 4. Hereinafter, the optical module according to an embodiment of the inventive concept will be described in detail with reference to FIG. 4 to

As illustrated in FIG. 4, the optical module 450 is positioned in the inner space 412. The optical module 450 heats the substrate M. The optical module 450 may heat the liquid-supplied substrate M. According to an embodiment, the optical module 450 may irradiate the laser into a region in which a specific pattern is formed among an entire area of the substrate M in which a liquid remains. For example, the optical module 450 may heat a second pattern P2 by irradiating the second pattern P2 shown in FIG. 3 with the laser. A temperature of the region at which the second pattern P2 irradiated with the laser is formed may increase. Accordingly, a degree of etching by the liquid may be relatively greater in a region in which the second pattern P2 is formed than in other regions of the substrate M.

In addition, the optical module 450 may image the region to which the laser is irradiated. For example, the optical module 450 may obtain an image of the region including the laser irradiated from the laser unit 500 to be described later.

The optical module 450 may include a housing 460, a moving unit 470, a head nozzle 480, a laser unit 500, a bottom reflective plate 600, an imaging unit 700, a lighting unit 800, and a top reflective member 900.

As illustrated in FIG.7 and FIG. 8, the housing 460 has an installation space therein. The installation space of the housing 460 may have an environment which is sealed from the outside. In the installation space of the housing 460, a part of the head nozzle 480, a laser unit 500, an imaging unit 700, and a lighting unit 800 may be positioned. The housing 460 protects the laser unit 500, the imaging unit 700, and the lighting unit 800 from byproducts or a scattering liquid generated during a process. The head nozzle 480, the laser unit 500, the imaging unit 700, and the lighting unit 800 may be modularized by the housing 460.

An opening may be formed at a bottom of the housing 460. The head nozzle 480 to be described later may be inserted into the opening formed at the housing 460. As the head nozzle 480 is inserted into the opening of the housing 460, a bottom part of the head nozzle 480 may protrude from the bottom end of the housing 460 as illustrated in FIG.4 and FIG. 7.

As illustrated in FIG. 4, the moving unit 470 is coupled to the housing 460. The moving unit 470 moves the housing 460. The moving unit 470 may a driving unit 472 and a shaft 474.

The driving unit 472 may be a motor. The driving unit 472 is connected to the shaft 473. The driving unit 472 may vertically and horizontally move the shaft 473. Also, the driving unit 472 may rotate the shaft 474 with the third direction 6 as an axis. Although not shown, the moving unit 470 according to an embodiment may include a plurality of driving units. Any one of the plurality of driving units may be a rotation motor for rotating the shaft 474, and another one of the plurality of driving units may be a linear motor for horizontally moving the shaft 474, and another of the plurality of driving units may be a liner motor for vertically moving the shaft 474.

The shaft 474 is coupled to the housing 460. As the shaft 474 moves or rotates in the horizontal direction by the driving unit 472, a position of the head nozzle 480 inserted into an opening formed in the housing 460 may also be changed on a horizontal plane. In addition, as the shaft 474 moves in the vertical direction, a height of the head nozzle 480 may be changed on the horizontal plane.

As illustrated in FIG. 7, the head nozzle 480 may have an objective lens and a barrel. The laser unit 500 to be described later may irradiate the laser to the target object through the head nozzle 480. The laser irradiated through the head nozzle 480 may have a generally flat-top shape when seen from above.

In addition, the imaging unit 700 to be described later may image the target object through the head nozzle 480. For example, the imaging unit 700 may image a region to which the laser is imaged to the target object, and may acquire an image including the laser. In addition, a light transmitted from the lighting unit 800 to be described later may be transmitted to the target object through the head nozzle 480. According to an embodiment, the target object may be the substrate M supported by the support unit 420. In addition, the target object may be a grid 427.

As illustrated in FIG.5 and FIG. 6, the head nozzle 480 may be moved between a process position and a standby position by the moving unit 470.

According to an embodiment, the process position may be a top side of the second pattern P2 formed on the substrate M supported by the support unit 420. For example, the process position may be a position which a center of a region formed on the second pattern P2 of the substrate M supported on the support unit 420 and a center of the head nozzle 480 overlap when seen from above.

According to an embodiment, the teaching position may be a top side of the teaching member 425. For example, when seen from above the teaching position may be a position at which the grid 427 and the head nozzle 480 overlap.

According to an embodiment, the standby position may an outer region of the treating container 430. A home port which is not shown may be positioned at the standby position. According to an embodiment, a maintenance operation of adjusting a state of the optical module 450 may be performed in the standby position.

The laser unit 500 illustrated in FIG. 7 irradiates the target object with the laser through the head nozzle 480. For example, if the head nozzle 480 is positioned in the process position, the laser unit 500 irradiates the laser to the substrate M supported by the support unit 420 through the head nozzle 480.

As illustrated in FIG. 7, the laser unit 500 may include an oscillation unit 520 and an expander 540. The oscillation unit 520 oscillates the laser. The oscillation unit 520 may oscillate the laser toward the expander 540. An output of the laser oscillated from the oscillation unit 520 may be changed according to a process requirement condition.

A tilting member 522 may be installed in the oscillation unit 520. The tilting member 522 may change an oscillation direction of the laser oscillated by the oscillation unit 520. According to an embodiment, the tilting member 522 may be a motor. The tilting member 522 may rotate the oscillation unit 520 based on an axis.

The expander 540 may include a plurality of lenses which are not shown. The expander 540 may change a divergence angle of the laser oscillated from the oscillator 520 by changing an interval between the plurality of lenses. Accordingly, the expander 540 may change a diameter of the laser oscillated from the oscillator 520. For example, the expander 540 may expand or reduce the diameter of the laser oscillated from the oscillation unit 520. The diameter of the laser is changed at the expander 540, and so a profile of the laser may be changed. According to an embodiment, the expander 540 may be provided as a variable beam expander telescope (BET). The laser which diameter is changed in the expander 540 is transmitted to a bottom reflective plate 600.

The bottom reflective plate 600 illustrated in FIG. 7 is positioned on a moving path of the laser oscillated from the oscillation unit 520. According to an embodiment, the bottom reflective plate 600 may be positioned at a height corresponding to the oscillation unit 520 and the expander 540 when viewed from a side. In addition, the bottom reflective plate 600 may be positioned to overlap the head nozzle 480 when seen from above. In addition, the bottom reflective plate 600 may be positioned to overlap the top reflective plate 960 to be described later when seen from above. The bottom reflective plate 600 may be disposed below the top reflective plate 960. The bottom reflective plate 600 may be tilted at the same angle as the top reflective plate 960.

The bottom reflective plate 600 may change a moving path of the laser oscillated from the oscillation unit 520. According to an embodiment, the bottom reflective plate 600 may change the moving path of the laser moving in the horizontal direction to a vertical downward direction. The laser which moving path is changed to the vertical downward direction by the bottom reflective plate 600 may be transmitted to the head nozzle 480. For example, the laser oscillated from the oscillation unit 520 may be irradiated to the second pattern P2 formed on the substrate M by sequentially passing through the expander 540, the bottom reflective plate 600, and the head nozzle 480.

The imaging unit 700 illustrated in FIG. 7 and FIG. 8 may image the laser irradiated to the target object. The imaging unit 700 may image a region irradiated with the laser. The imaging unit 700 may obtain an image of the target object including a region irradiated with the laser. As illustrated, the target object may be a substrate M supported by the support unit 420 or the grid 427.

The imaging unit 700 may be a camera module. According to an embodiment, the imaging unit 700 may be a camera module in which a focus is automatically adjusted. Also, the imaging unit 700 may be a camera module for irradiating a visible light or a far-infrared light. The image acquired by the imaging unit 700 may be a video and/or a photo. The imaging direction of the imaging unit 700 may be directed toward the top reflective plate 960. The imaging direction of the imaging unit 700 may be changed from a horizontal direction to a vertical downward direction by the top reflective plate 960. For example, the imaging direction of the imaging unit 700 may be changed to a direction toward the head nozzle 480 by the top reflective plate 960. Accordingly, the imaging unit 700 may acquire an image of the target object by imaging the target object through the head nozzle 480.

The lighting unit 800 illustrated in FIG. 8 transmits the lighting to the target object so that the imaging unit 700 may easily obtain the image of the target object. The light transmitted by the lighting unit 800 may face the first reflective plate 920 to be described later. The light transmitted to the first reflective plate 920 may move sequentially through the second reflective plate 940 and the top reflective plate 960 to be transmitted to the target object through the head nozzle 480.

The top reflective member 900 may include a first reflective plate 920, a second reflective plate 940, and a top reflective plate 960.

The first reflective plate 920 and the second reflective plate 940 may be installed at a height corresponding to each other. The first reflective plate 920 may change a direction of the light transmitted by the lighting unit 800. The first reflective plate 920 may reflect the light received in a direction toward the second reflective plate 940. The second reflective plate 940 may change a direction of the light transmitted by the first reflective plate 920. The second reflective plate 940 may reflect the light received from the first reflective plate 920 in a direction toward the top reflective plate 960.

The top reflective plate 960 and the bottom reflective plate 600 may be disposed to overlap when seen from above. The top reflective plate 960 may be disposed above the bottom reflective plate 600. The top reflective plate 960 and the bottom reflective plate 600 may be tilted at the same angle as described above.

The top reflective plate 960 may change the imaging direction of the imaging unit 700 and the lighting transmission direction of the lighting unit 800 to the direction toward the head nozzle 480. Accordingly, the imaging direction of the imaging unit 700 and the lighting direction of the lighting unit 800 may be coaxial with the irradiation direction of the laser which moving path has been changed in the direction toward the head nozzle 480 by the bottom reflective plate 600. In other words, the direction in which the laser unit 500 irradiates the laser to the target object through the head nozzle 480, the direction in which the imaging unit 700 images the target object through the head nozzle 480, and the direction in which the lighting unit 800 transmits a light to the target object may overlap when viewed from above.

Unlike the above-described example, drying chambers (not shown) may be further disposed on a side of the transfer frame 300. In the drying chamber (not shown), the substrate on which a liquid treatment and/or a heat treatment is completed may be dried in the chamber 400. The chamber 400 may be disposed on a side portion of the transfer frame 300 relatively adjacent to the buffer unit 200 than the drying chamber (not shown).

Hereinafter, a modified embodiment of the chamber according to an embodiment of the inventive concept will be described. Since the chamber in accordance with the embodiment described below is mostly the same as or similar to the configuration of the chamber described above, except for a case in which it is additionally described, a description of the redundant contents will be omitted.

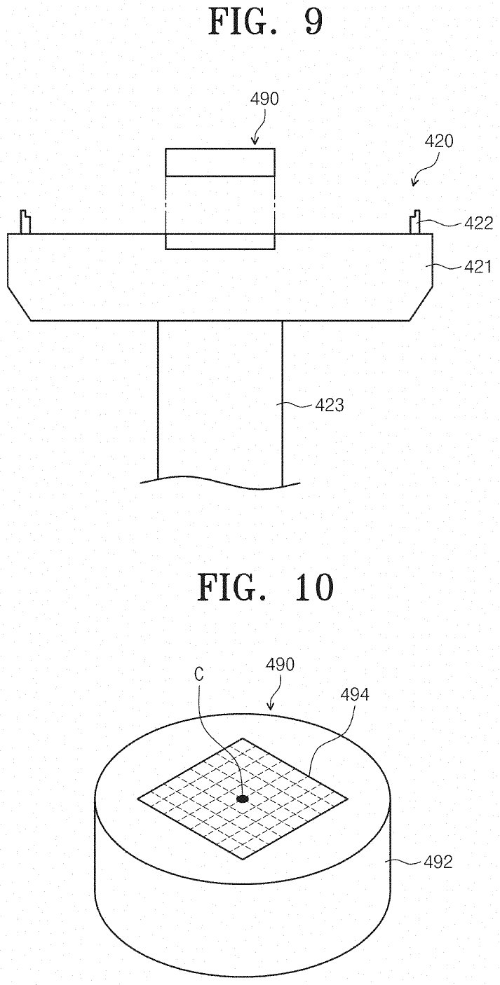

FIG. 9 schematically illustrates a front view of the support unit and the teaching member according to another embodiment of FIG. 4. FIG. 10 is a perspective view of the teaching member of FIG. 9.

Referring to FIG. 9, a groove may be formed in a center region including a center of the main body 421. For example, a top surface of the center region of the main body 421 may be stepped lower than a top surface of the edge region surrounding the center region of the main body 421. The teaching member 490 to be described later may be inserted into the center region of the main body 421. A support pin 422 may be disposed in the edge region of the main body 421.

Referring to FIG. 9 and FIG. 10, the teaching member 490 may include a body 492 and a grid 494. The body 492 may have a shape corresponding to the groove formed in the main body 421. The body 492 may be inserted into the groove formed in the main body 421. The body 492 is detachable from the main body 421. A fixing jig which is not shown may be installed on the body 492. The fixing jig may fix the body 492 to the main body 421. However, the inventive concept is not limited thereto, and after the body 492 is inserted into the groove formed in the main body 421, the body 492 may be fixed to the main body 421 using various known methods.

A height from the top surface to the bottom surface of the body 492 may be greater a height of the groove formed in the center region of the main body 421. In addition, with the body 492 inserted into the groove of the main body 421, the top part of the body 492 may upwardly protrude from the top surface of the edge region of the main body 421. In addition, in a state at which the body 492 is inserted into the groove of the main body 421, the top end of the body 492 may be positioned below the top end of the support pin 422. In addition, with the body 492 inserted into the groove of the main body 421 and the substrate M seated on the support pin 422, the top end of the body 492 may be positioned below the bottom surface of the substrate M.

The grid 494 may be positioned on the top surface of the body 492. A top end of the grid 494 and a top end of the body 492 may have the same height. Accordingly, while the body 492 is inserted into the groove of the main body 421, the top end of the grid 494 may be positioned below the top end of the support pin 422. In addition, with the body 492 inserted into the groove of the main body 421 and the substrate M seated on the support pin 422, the top end of the grid 494 may be positioned below the bottom surface of the substrate M.

Hereinafter, a substrate treating method according to an embodiment of the inventive concept will be described in detail. The substrate treating method described below may be performed in the chamber 400 according to the above-described embodiment. In addition, the controller 30 may control the components of the chamber 400 so as to perform the substrate treating method described below.

Hereinafter, for convenience of understanding, an embodiment in which the teaching member is coupled to the support unit will be described as an example, but the same or similar mechanism may be performed in the support unit and the teaching member described with reference to FIG. 9 and FIG. 10.

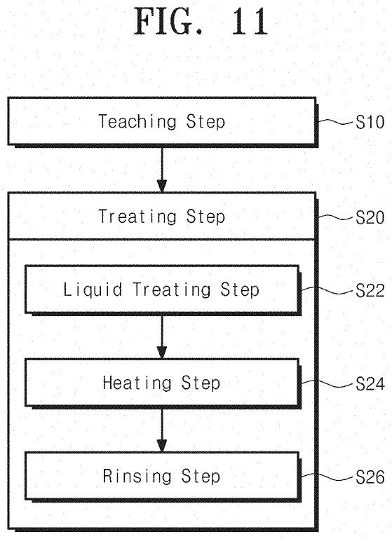

FIG. 11 is a flowchart of a substrate treating method according to an embodiment of the inventive concept. Referring to FIG. 11, a substrate treating method according to an embodiment of the inventive concept may include a teaching step S10 and a treating step S20. The teaching step S10 may be performed before the treating step S20 is performed. For example, the teaching step S10 may be performed before the substrate M is taken into an inner space 412 of the chamber 400.

In the teaching step S10, a center position of a laser irradiated through the head nozzle 480 may be taught. According to an embodiment, a center of the head nozzle 480 and a center of the laser irradiated through the head nozzle 480 may be the same when viewed from above. Accordingly, in the teaching step S10, the center position of the laser irradiated to the target object through the head nozzle 480 may be taught by teaching the center position of the imaging area imaging the target object through the head nozzle 480.

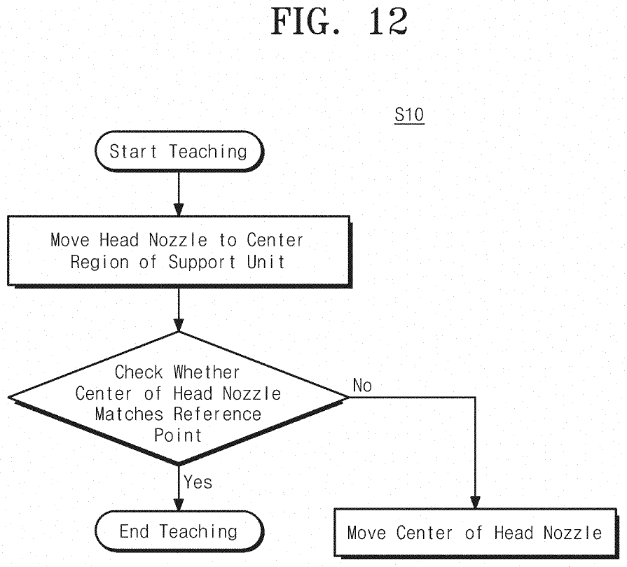

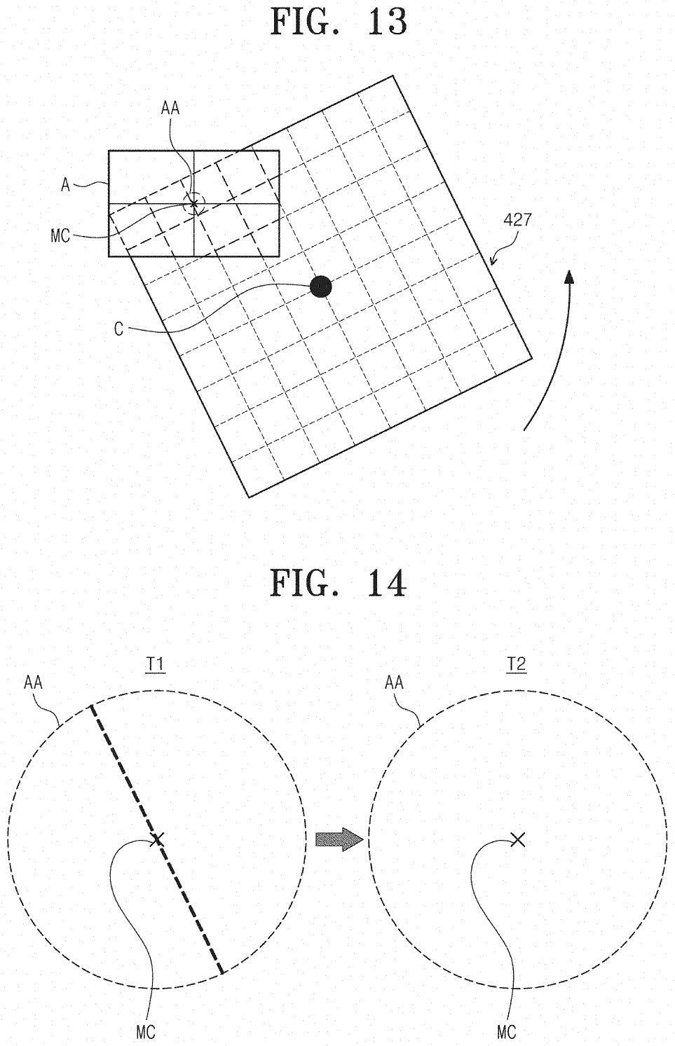

FIG. 12 is a block diagram schematically illustrating an order of the teaching step of FIG. 11. FIG. 13 illustrates a state in which the head nozzle is upwardly moved from a top side of the grid in the teaching step of FIG. 11.

Referring to FIG. 12 and FIG. 13, in the teaching step S10, the head nozzle 480 is upwardly moved in the center region including the center of the support unit 420. As described above, the teaching member 425 is positioned in the center region of the support unit 420. Accordingly, in the teaching step S10, the head nozzle 480 is upwardly moved from the teaching member 425. According to an embodiment, in the teaching step S10, the head nozzle 480 is upwardly moved from the grid 427.

If the head nozzle 480 is positioned at a top side of the grid 427, the support unit 420 illustrated in FIG. 4 rotates. If the head nozzle 480 is positioned at a top side of the grid 427, the imaging unit 700 images the rotating grid 427. The imaging unit 700 acquires an image of the grid 427 by imaging the rotating grid 427. According to an embodiment, the image of the grid 427 acquired by the imaging unit 700 may be an image. The imaging unit 700 transmits the acquired image to the controller 30.

The controller 30 checks whether the center of the head nozzle matches a reference point C displayed on the grid 427. The controller 30 can check whether the center of the imaging region imaged by the imaging unit 700 matches the reference point C, and check whether the center of the laser irradiation and the center of the head nozzle match the reference point C. Hereinafter, a mechanism by which the controller 30 checks whether the center of the imaging region and the reference point C coincide with each other will be described in detail.

FIG. 14 illustrates an image in a set region among images of a grid acquired through a head nozzle which has been moved upward in the grid of FIG. 13 in a time order.

Referring to FIG. 13 and FIG. 14, the controller 30 may set a set region AA of an entire region A of an image of the grid 427 received from the imaging unit 700. The set region AA may refer to a region including a point which becomes a center MC among all regions A of the image. A point serving as the center MC among the entire region A of the image may coincide with a center of the imaging region imaged by the imaging unit 700. In addition, the set region AA may have a region corresponding to the reference point C displayed on the grid 427. For example, assuming that the center MC and the reference point C displayed on the grid 427 are positioned on the same axis, the set region AA and the reference point C may overlap each other when viewed from above.

The controller 30 may calculate the number of grids passing through the set region AA. According to an embodiment, the controller 30 may calculate the number of grids passing through the set region AA during a set time. The set time may be defined as a time required for the substrate M supported by the support unit 420 illustrated in FIG. 4 and the like to rotate once in a process of performing a treating step S20 to be described later. However, the above-described definition of an explanation time is for illustrative purposes only and is not limited thereto.

The controller 30 calculates the number of grids passing through the set region AA during the set time, and calculates a variation value of the calculated number of grids. For example, as shown in FIG. 14, the controller 30 determines whether a grid passes through the set area AA among the images acquired at a first time point T1 and whether a grid passes through the set area AA among the images acquired at a second time point T2. The second time point T2 may be a time point at which a very short time has elapsed from the first time point T1.

As shown in FIG. 14, since the image acquired by the controller 30 is an image of the rotating grid 427, the controller 30 can determine that there is a grid passing through the set region AA at the first time point T1 and that there is no grid passing through the set region AA at the second point T2. Accordingly, the controller 30 may calculate that the number of grids passing through the set region AA as time elapses from the first time point T1 to the second time point T2 is 1. The controller 30 may repeatedly perform such a mechanism for a set time. For example, as shown in FIG. 13, if the center MC of the image acquired by the imaging unit 700 by imaging the grid 427 is positioned near an outermost part of the grid 427, the controller 30 may calculate that the number of grids passing through the set area is 64 during the set time.

The controller 30 may move the head nozzle 480 if the number of grids passing through the set region AA does not correspond to zero during the set time. The controller 30 may move the head nozzle 480 to a position at which the number of grids passing through the set region AA becomes smaller during the set time. Accordingly, as shown in FIG. 13, the controller 30 may move the head nozzle 480 positioned near the outermost part of the grid 427 in a direction toward the center of the grid 427. It is natural that the number of grids passing through the set region AA during the set time calculated by the controller 30 is less in the central area of the grid 427 than in the edge region of the grid 427. That is, the controller 30 may move the head nozzle 480 in a direction toward the reference point C.

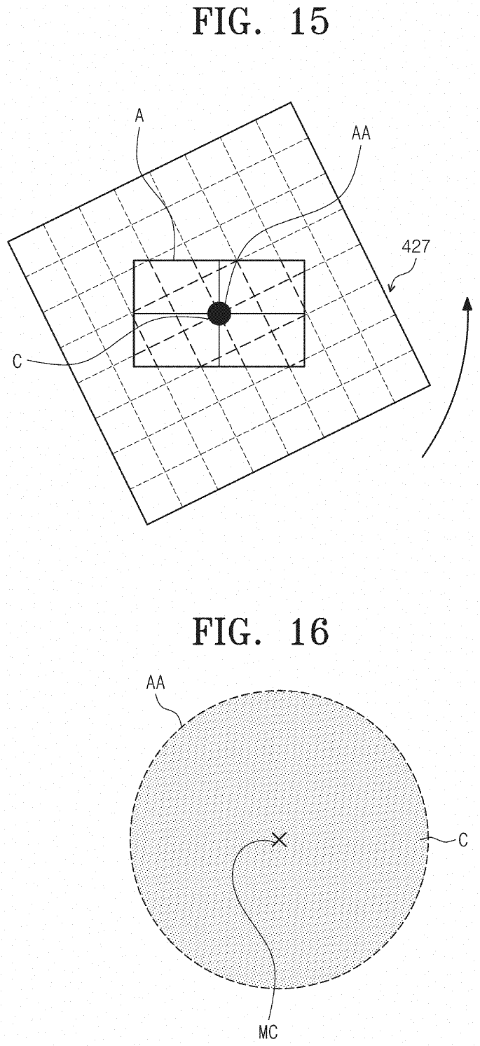

FIG. 15 illustrates a state in which the center of the imaging region moves to the reference point of the grid in the teaching step of FIG. 11. FIG. 16 schematically illustrates an image in the set region among images of the grid acquired through the head nozzle of FIG. 15.

The controller 30 may move the head nozzle 480 until the number of grids passing through the set region AA becomes zero during the set time. As illustrated in FIG. 15, if the center of the imaging area imaged by the imaging unit 700 coincides with the reference point C, as illustrated in FIG. 16, the number of grids passing through the set region AA during the set time calculated from the image acquired by the controller 30 may be 0. If the number of grids passing through the set region AA becomes zero during the set time, the controller 30 stops a movement of the head nozzle 480 and ends the teaching step S10.

Referring back to FIG. 11, the treating step S20 may include a liquid treating step S22, a heating step S24, and a rinsing step S26. According to an embodiment, the liquid treating step S22 and the heating step S24 may be combined to be referred to as an etching step. In the etching step, a pattern formed on the substrate M may be etched. For example, it is possible to etch a specific pattern (e.g., a second pattern P2) formed on the substrate M so that a critical dimension of the first pattern P1 formed on the substrate M of FIG. 3 coincides with the critical dimension of the second pattern P2 formed on the substrate M of FIG. 3. The etching step may refer to a critical dimension correction process for correcting a difference between the critical dimensions of the first pattern P1 and the second pattern P2.

In the liquid treating step S22, the liquid supply unit 440 may supply a chemical, which is an etchant, to the substrate M supported by the support unit 420. In the liquid treating step S22, a chemical may be supplied to the substrate M which rotation is stopped. If the chemical is supplied to the substrate M at which the rotation is stopped, the chemical supplied to the substrate M can be supplied in an amount sufficient to form a puddle. For example, if the chemical is supplied to the substrate M which rotation is stopped in the liquid treating step S22, an amount of a supplied chemical may cover an entire top surface of the substrate M, and may be supplied so that the amount is not large even if the chemical does not flow from the substrate M or flows down. If necessary, the chemical may be supplied to the entire top surface of the substrate M while the nozzle 441 changes its position.

After completing the liquid treating step S22 by supplying the chemical to the substrate M, the controller 30 may move the optical module 450 to the process position. A process position may be previously stored in the controller 30. For example, a region in which the second pattern P2 is formed for each substrate M may be different. Accordingly, if the pre-treated substrate M is taken into the inner space 412 to be treated by the chamber 400, the controller 30 may store position coordinates from the center of the substrate M on which a pre-treatment has been completed and is being taken into to the center of the region at which the second pattern P2 is formed on the substrate M.

In the teaching step S10, the controller 30 moves the head nozzle 480 which center is are aligned with the reference point C. As described above, the reference point C may coincide with the center of the substrate M supported by the support unit 420 when viewed from above. Accordingly, the controller 30 may move the center of the head nozzle 480 from the reference point C to the top side of the center of a region at which the second pattern P2 is formed on the substrate M using stored position coordinates.

The heating step S24 starts when the center of the head nozzle 480 corresponds to the center of the region at which the second pattern P2 is formed when viewed from above. In the heating step S24, the substrate M is heated by irradiating the substrate M with a laser. According to an embodiment, in the heating step S24, the substrate M may be heated by irradiating the laser onto the second pattern P2 formed on the substrate M.

A temperature of the region at which the second pattern P2 irradiated with the laser is formed may increase. Accordingly, an etching rate by a chemical already supplied in the region at which the second pattern P2 is formed may increase. Accordingly, the critical dimension of the first pattern P1 may be changed from a first width (e.g., 69 nm) to a target critical dimension (e.g., 70 nm). In addition, the critical dimension of the second pattern P2 may be changed from a second width (e.g., 68.5 nm) to a target critical dimension (e.g., 70 nm). That is, in the heating step S24, an etching ability of a partial region of the substrate M is improved, thereby minimizing a critical dimension deviation of the pattern formed on the substrate M.

To precisely irradiate the laser with the second pattern P2, the center of the head nozzle 480 should be positioned above the center of the region at which the second pattern P2 is formed. In the teaching step S10, the center of the imaging region is adjusted to the reference point C. Accordingly, the center of the head nozzle 480 is also adjusted to the reference point C. In addition, the irradiation center of the laser irradiated through the head nozzle 480 is adjusted to the reference point C. The reference point C corresponds to the center of the substrate M when viewed from above. The coordinates of the center of the region at which the second pattern P2 is formed on the substrate M are calculated based on the center of the substrate M. That is, according to an embodiment of the inventive concept, by accurately teaching the center of the head nozzle 480 as the reference point C in the teaching step S10, the center of the head nozzle 480 may move accurately to the top side of the center of the region at which the second pattern P2 is formed. Accordingly, in the heating step S24, the second pattern P2 may be collectively and accurately heated by irradiating a region at which the second pattern P2 is formed.

In addition, according to an embodiment of the inventive concept, an irradiation center of the laser can be adjusted by adjusting the center of the imaging area in the teaching step S10, so that a position at which the laser is irradiated to the target object can be adjusted more efficiently.

After the heating step S24 is completed, the rinsing step S26 may be performed. After the heating step S24 is completed, the optical module 450 may move from the process position to the standby position. In the rinsing step S26, the liquid supply unit 440 may supply a rinsing liquid to the rotating substrate M. In the rinsing step S26, the rinsing liquid may be supplied to the substrate M to remove byproducts attached to the substrate M. In addition, in order to dry the rinsing liquid remaining on the substrate M as necessary, the support unit 420 can remove the rinsing liquid remaining on the substrate M by rotating the substrate M at a high speed.

In the above example, the controller 30 calculates the number of grids passing through the set region AA during the set time and changes the center position of the imaging area of the imaging unit 700 using the calculated number of grids, but is not limited thereto. For example, the controller 30 may change the center position of the imaging region of the imaging unit 700 from a radial shape of the grid which changes as the grid 427 rotates in the image acquired by the imaging unit 700. For example, the controller 30 may move the head nozzle 480 from a position at which there are many changes in the radial shape of the grid to a position at which there are few changes. Preferably, the controller 30 may move the head nozzle 480 to a position at which the radial shape of the grid is minimized A position at which the change in the radial shape of the grid is minimized may be a point at which the center of the imaging region and the reference point C coincide.

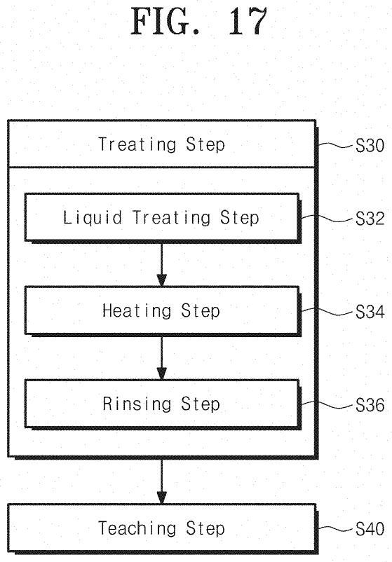

FIG. 17 is a flowchart of a substrate treating method according to another embodiment of FIG. 11. Referring to FIG. 17, a substrate treating method according to an embodiment of the inventive concept may include a treating step S30 and a teaching step S40. The treating step S30 according to an embodiment is mostly the same as or similar to the treating step S20 described with reference to FIG. 11, and the teaching step S40 is mostly the same as or similar to the teaching step S10 described with reference to FIG. 11 or less. However, the teaching step S40 according to an embodiment of the inventive concept may be performed after the treating step S30 is completed.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a support unit configured to rotate and support a substrate;
a liquid supply unit configured to supply a liquid to the substrate supported on the support unit; and
an optical module for heating the substrate supported on the support unit, and wherein the support unit includes a teaching member having a grid displaying a reference point which matches a center of the support unit.

2. The substrate treating apparatus of claim 1, wherein a top surface of the teaching member is positioned below a bottom surface of the substrate supported on the support unit.

3. The substrate treating apparatus of claim 2, wherein the optical module includes:
a laser unit configured to irradiate a laser to the substrate supported on the support unit through a head nozzle; and
an imaging unit configured to acquire an image by imaging a target object through the head nozzle.

4. The substrate treating apparatus of claim 3, wherein an irradiation direction of the laser irradiated through the head nozzle and an imaging direction imaging the target object through the head nozzle are coaxial.

5. The substrate treating apparatus of claim 4 further comprising a controller for controlling the support unit and the optical module, and
wherein the controller moves the head nozzle to a top side of the teaching member which rotates at a constant speed, acquires an image including the grid by imaging the rotating teaching member, and
calculates the number of grids passing through a set region including a center of the image among an entire region of the image during a set time, and moves the center of the head nozzle to the reference point based on a change in the number of grids.

6. The substrate treating apparatus of claim 5, wherein the controller moves the head nozzle from a position having a large number of grids to a position having a relatively small number of the grids which pass the set region during the set time.

7. The substrate treating apparatus of claim 6, wherein the controller stops a movement of the head nozzle if the number of grids passing the set region during the set time becomes 0.

8. The substrate treating apparatus of claim 1, wherein the support unit further comprises a support pin for supporting the substrate, and
the teaching member is positioned at a center region which includes a center of the support unit, and
the support pin is positioned at an edge region which supports a center region of the support unit.

9. The substrate treating apparatus of claim 8, wherein the teaching member is detachable from a top part of the support unit.

10. The substrate treating apparatus of claim 8, wherein the teaching member couples to the top part of the support unit.

11. The substrate treating apparatus of claim 3, wherein a center of the head nozzle, a center of the laser irradiated through the head nozzle, and a center of the imaging region of the imaging unit match each other.

12-18. (canceled)

19. A substrate treating apparatus for treating a mask having a plurality of cells comprising:
a support unit configured to support the mask having a first pattern formed within the plurality of cells, and a second pattern formed outside a region at which the cells are formed and which is different from the first pattern;
a liquid supply unit configured to supply a liquid to a mask supported on the support unit; and
an optical module for heating the mask supported on the support unit, and wherein the support unit includes:
a support pin for supporting the mask; and
a teaching member having a grid displaying a reference point which matches the support unit, and
wherein the optical module includes:
a head nozzle;
a laser unit configured to irradiate a laser to the mask through the head nozzle; and
an imaging unit configured to image a target object through the head nozzle, and
wherein the teaching member is positioned at a center region including a center of the support unit, and
the support pin is positioned at an edge region surrounding a center region of the support unit, and
a top surface of the teaching member is positioned below a bottom surface of the mask supported on the support unit, and
wherein an irradiation direction of the laser irradiated through the head nozzle and an imaging direction imaging the target object through the head nozzle are coaxial, and a center of the laser irradiated through the head nozzle and a center of the imaging region imaging the target object through the head nozzle correspond when seen from above.

20. The substrate treating apparatus of claim 19 further comprising a controller for controlling the support unit and the optical module, and
wherein the controller moves the head nozzle to a top side of the teaching member which rotates at a constant speed, acquires an image including the grid by imaging the rotating teaching member, and
calculates the number of grids passing through a set region including a center of the image among an entire region of the image during a set time, and stops a movement of the head nozzle until the number of grids passing the set region during the set time becomes 0.
